(19) United States
(12) Patent Application Publication
(10) Pub. No.: US 2010/0017158 A1
(43) Pub. Date: Jan. 21, 2010

(54) GENERATING WORST CASE BIT PATTERNS FOR SIMULTANEOUS SWITCHING NOISE (SSN) IN DIGITAL SYSTEMS

(75) Inventors: Rohan Mandrekar, Austin, TX (US); Paul Marlan Harvey, Austin, TX (US); Yaping Zhou, Austin, TX (US); Kazushige Kawasaki, Nagahama (JP)

Correspondence Address: IBM Austin IPLaw;(c/o), THE LAW OFFICE OF ROBERT A. MCLAUCHLAN, Post Office Box 26780, AUSTIN, TX, 78755, US

(73) Assignee: International Business Machines Corporation

(21) Appl. No.: 12/176,811

(22) Filed: Jul. 21, 2008

(51) Int. Cl. G01R 29/26

(52) U.S. Cl. 702/69

(57) ABSTRACT

A methodology to determine a bit pattern that may excite a worse case or near worse case simultaneous switching noise on a memory or input/output (IO) interface of a digital system is provided. This methodology involves determining an impedance profile of the IO interface of the digital system. The amplitude response of signal X_{(f)} may be matched in the impedance profile of the IO interface. The phase response of the signal X_{(f)} is also set. The signal X_{(f)} having a matched amplitude response may be converted from a frequency domain signal to a time domain signal to produce a signal X₍ₜ₎. Signal X₍ₜ₎ the time domain signal X₍ₜ₎ may be digitized to represent a bit stream B₍ₜ₎. This bit stream may be used as a switching pattern to determine simultaneous switching noise of the IO interface of the digital system

### BACKGROUND OF THE INVENTION

The present invention relates generally to the analysis of electronic circuits under various conditions, and more particularly, a system and method for analyzing the effects of simultaneous switch noise (SSN) in electronic systems.

As the density of integrated circuits (ICs) increases, the problems associated with signal switching noise become greater. Many ICs have a large number of input/output (IO) drivers; and that number will only increase as packaging density increases. Noise within an electronic system may occur when drivers simultaneously switch from one state to another. This noise is known as simultaneous switch noise (SSN). Problems associated with SSN may be even more acute when multiple drivers switch in the same direction. Drivers switching simultaneously may cause various signal integrity problems. For example, SSN may result in erroneous noise pulses on signal lines, alter system timing, may cause receivers of other chips in an electronic system, or receivers on the same chip, to receive incorrect results, power supply fluctuations severe enough to cause damage to the circuits comprising the load, or even internal damage to the power supplies.

Many problems are associated with prior SSN analysis techniques. The use of ideal power supplies in the simulation is one such problem. An ideal power supply is a power supply that has zero output impedance. In reality, such power supplies do not exist. An ideal power supply may be configured to provide a constant voltage between its terminals regardless of the behavior of the load circuit. Thus, such analysis techniques employing ideal power supplies may fail to account for power supply fluctuations that may occur due to the simultaneous switching of a large number of drivers.

With the problems mentioned above, it has become increasingly difficult to get accurate results to simulations of the SSN problem. Often times, results from a simulation and analysis will not have any meaningful correlation to the SSN problem of hardware that is built based on such analysis.

### BRIEF SUMMARY OF THE INVENTION

Embodiments of the present invention are directed to systems and methods that are further described in the following description and claims. Advantages and features of embodiments of the present invention may become apparent from the description, accompanying drawings and claims.

Embodiment to the present invention provides a methodology to determine a bit pattern that may excite a worst case or near worse case simultaneous switching noise (SSN) on a memory or input/output (IO) interface of a digital system. This methodology involves determining an impedance profile of the IO interface of the digital system. The amplitude response of signal X_{(f)} may be matched in the impedance profile of the IO interface. The phase response of the signal X_{(f)} is also set. The signal X_{(f)} having a matched amplitude response may be converted from a frequency domain signal to a time domain signal to produce a signal X₍ₜ₎. Signal X₍ₜ₎ the time domain signal X₍ₜ₎ may be digitized to represent a bit stream B₍ₜ₎. This bit stream may be used as a switching pattern to determine simultaneous switching noise of the IO interface of the digital system.

Another embodiment of the present invention provides a model of a digital system and a computer system. The computer system may be configured to determine an impedance profile of an IO interface of the digital system based on the model. An amplitude response of a signal X_{(f)} may be matched to an impedance profile based on the model of the digital system. The phase response to the signal X_{(f)} may also be set. The signal X_{(f)} may be converted from a frequency domain signal to a time domain signal. This time domain signal may be digitized to produce a bit stream. The bit stream may be used to simulate simultaneous switching of the IO interface to determine simultaneous switching noise.

Yet another embodiment of the present invention provides a method for analyzing SSN within a digital system. This involves providing a model of the digital system. An impedance profile of the IO interface of the digital system may then be determined based on the model of the digital system. The amplitude response of a frequency domain signal may be matched to the impedance profile of the IO interface. The phase response may be set of the frequency domain signal. The frequency domain signal may be converted from a frequency domain to a time domain wherein the signal and the time domain may be digitized to represent a bit stream that may be used as a switching pattern for the IO interface of the digital system in order to determine simultaneous switching noise.

### BRIEF DESCRIPTION OF THE SEVERAL VIEWS OF THE DRAWINGS

For a more complete understanding of the present invention and the advantages thereof, reference is now made to the following description taken in conjunction with the accompanying drawings in which like reference numerals indicate like features and wherein:

FIG. 1 provides a block diagram describing the architecture of a system on a chip (SoC) integrated circuit (IC);

FIG. 2 provides an IO impedance profile Z_{(f)} having resonant behavior in the 200 to 300 megahertz region;

FIG. 3 shows an impedance Z_{(f)} profile and a switching current I_{(f)} profile offered by prior art solutions;

FIG. 4 shows a switching current I_{(f)} profile associated with the frequency response of a perfectly random bit pattern having a uniform frequency spectrum;

FIG. 5 provides a logic flow diagram of a methodology of generating a pseudo random bit pattern with desired harmonic properties in accordance with embodiments of the present invention;

FIG. 6 provides a switching current I_{(f)} profile associated with the pseudo random bit pattern generated as described with reference to FIG. 5 in accordance with embodiments of the present invention;

FIG. 7 provides a direct comparison of the results from a pseudo random bit pattern in accordance with embodiments of the present invention and a repetitive bit pattern;

FIG. 8 provides a table of SSN measurements associated with a pseudo random bit pattern in accordance with embodiments of the present invention and various repetitive bit patterns;

FIG. 9 provides a system operable to implement a methodology to determine a bit pattern that approximates a worst case SSN for memory or IO interfaces of digital systems in accordance with embodiments of the present invention; and

FIG. 10 provides a logic flow diagram of a methodology of generating a pseudo random bit pattern with desired harmonic properties in accordance with embodiments of the present invention.

### DETAILED DESCRIPTION OF THE INVENTION

Preferred embodiments of the present invention are illustrated in the FIGs., like numerals being used to refer to like and corresponding parts of the various drawings.

Embodiments of the present invention provide a methodology to determine a bit pattern that may excite a worst case or near worse case simultaneous switching noise (SSN) on a memory or input/output (IO) interface of a digital system. This enables a more accurate estimation of SSN effects on the IO interface. This may also provide for a reduction in the number of simulations required to estimate a worst case SSN. Resulting in an overall reduction of the simulation time required to estimate the worst case SSN.

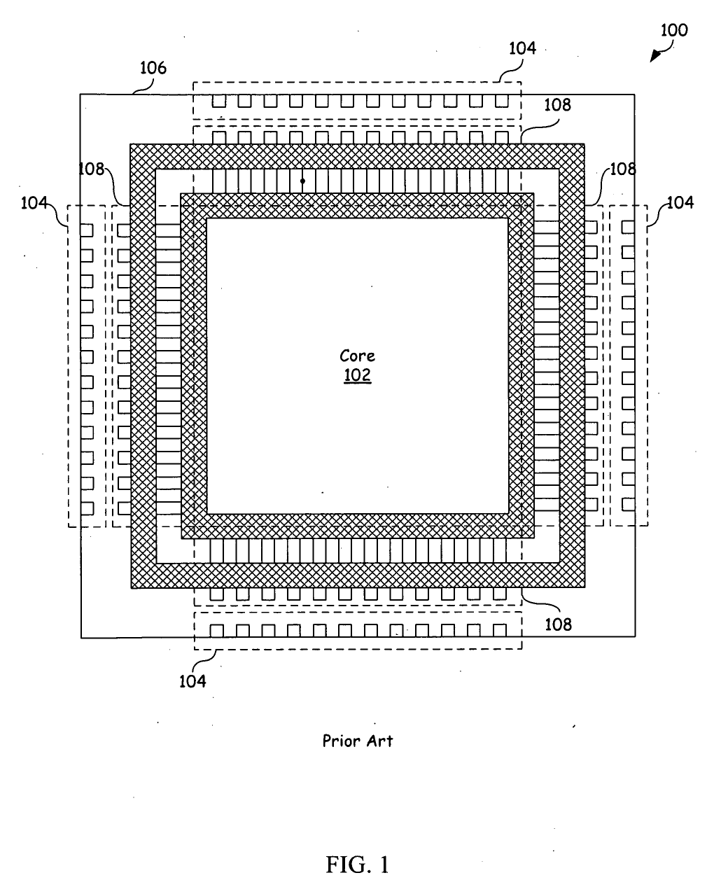

FIG. 1 depicts an IC or system on a chip (SoC) 100 that may include many logic and memory functions within the SoC. For example, core 102, may include a CPU core, DSP core, DSP book, memory, control circuitry and analog/mixed signal circuitry. These are just examples of the types of systems or components that may be integrated into a signal chip.

Complexities are associated with the realization of SoC designs. Incorporating diverse components previously contained within printed circuit board (PCB) involves confronting many design challenges. The discrete components may be designed for different entities using different tools. Other difficulties lie in fabrication. In general, fabrication processes of memory may differ significantly from those associated with logic circuits. For example, speed may be the priority associated with a logic circuit while current leakage of the stored charge is of priority for memory circuits. Therefore, multi-level interconnect schemes using five to six levels of metal are essential for logic ICs in order to offer improved speed, while memory circuits may need only two to three levels.

In order for the IC to be useful, the IC must have physical connections to the outside world. Two extremes in IC development support different types of interfaces to external devices. Low cost packaging which supports low pin count is achieved with traditional wire bond attached chips. High cost packaging may support high pin count in the case of flip chips.

With wire bond attached chips such as IC 10 as illustrated in FIG. 1, pads 104, IO cells 108 are placed at the edge of die 106. IO cells 108 may be decoupled from core circuitry 102 by isolation structures. This ensures that electrical noise is not coupled into core 102. Additional circuitry for latch up and electrostatic discharge (ESD) protection may be placed within cells that form a ring around the dye which is called the IO pad ring. Bond wire pads 104 are placed at the edge of the die outside IO circuitry.

Traditional ICs fall into two general categories, core-limited and IO or pad limited. A core-limited chip is one where the size of the chip is dependent on the amount of logic contained therein. The perimeter of the chip is more than sufficient to support the IO, clock, power, and ground bonding pads surrounding the core. A pad-limited IC's size is dictated by the bonding pads on the die's perimeter, wherein pads 104 are as close as possible, consistent with the IC's design rules. Thus pad limited IC's often contain wasted open space within die.

Advances in device density within the core have made it possible to reduce core size of IC devices. However, reduced IO pad pitch (the pitch is typically defined as the repeat distance between adjacent IO pads 104) has been hard to achieve because of packaging limitations. Therefore, as a result, IC designs that are IO intensive tend to have a die size significantly greater than that of the core.

IO drivers 108, the primary means by which a chip drives output signals, must have low resistance access to chip ground and power. The power required by these drivers needs to be supplied all the way from the power supply outlet, through the voltage regulator module (VRM), through a printed circuit board (PCB), through the chip package up to the chip power and ground that connects to the IO drivers. An IO power distribution network (PDN) comprises of some or all of the above mentioned components. Since IO drivers need power to be supplied across a range of frequencies, the PDN is ideally required to have zero impedance across all frequencies. In reality however, the PDN has finite impedance that varies with frequency depending upon the design of the various components (like VRM, PCB, package etc) in the system. A plot of this PDN impedance against frequency is called an IO impedance profile.

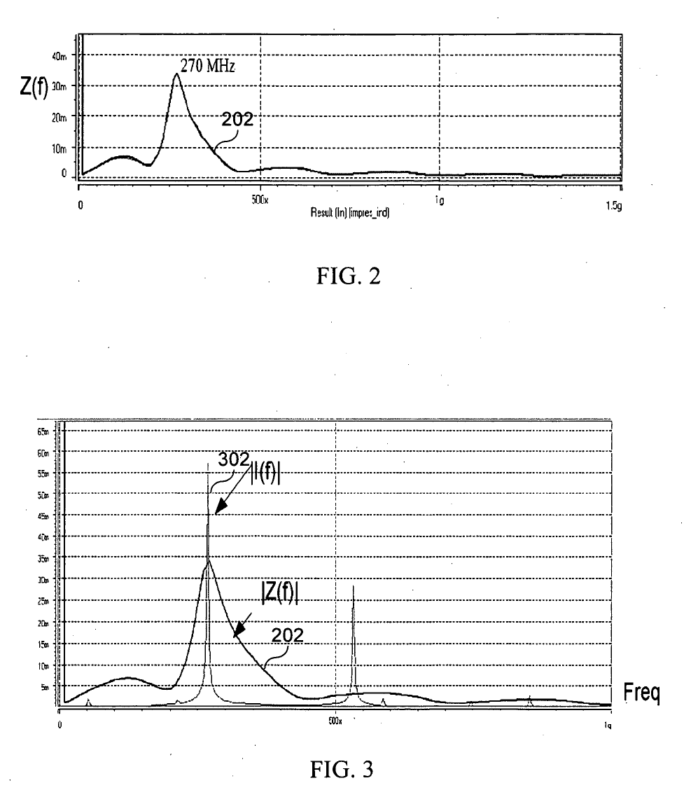

FIG. 2 provides an IO impedance profile Z_{(f)} 202 of a digital system or electronic circuit having a resonant behavior in the 200 to 300 megahertz region. Prior techniques use a bit pattern based on peak frequency of the resonance region. For example, FIG. 3 shows an impedance profile Z_{(f)} 202 and a switching current I_{(f)} profile 302 offered by prior art solutions. A repetitive pattern is chosen such that switching current I_{(f)} 302 peaks in the resonance region. However, as compared with the impedance profile Z_{(f)} a large portion of the resonance region Z_{(f)} remains unexcited. If there are additional I_{(f)} harmonics in this resonant region a worse SSN should result. Furthermore, depending upon the phase relationship the additional harmonics could be added (giving a worse SSN) or subtracted (giving a lesser SSN) to the interface.

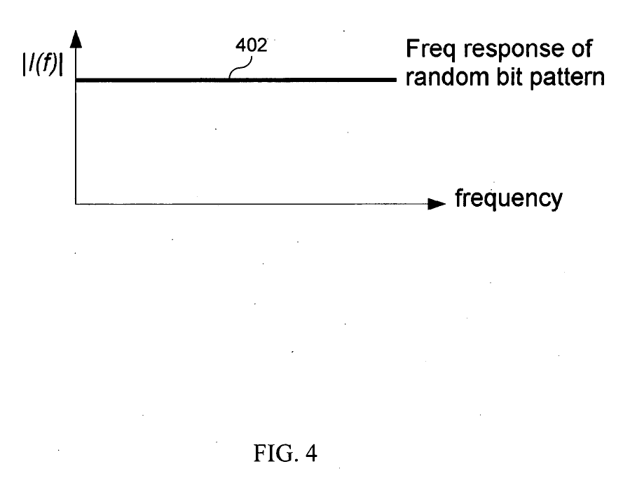

To determine the worst possible case, the bit pattern can be randomized to begin with. However, a perfectly random bit pattern has a uniform frequency spectrum. Hence, much of the excitation energy is wasted in non-resonant regions of the power spectrum. FIG. 4 shows the frequency response 402 of a perfectly random bit pattern having a uniform frequency spectrum. Embodiments of the present invention do away with the repetitive bit pattern having narrow peaks associated within resonant regions of the impedance profile in favor of a pseudorandom bit pattern generated in accordance with embodiments of the present invention.

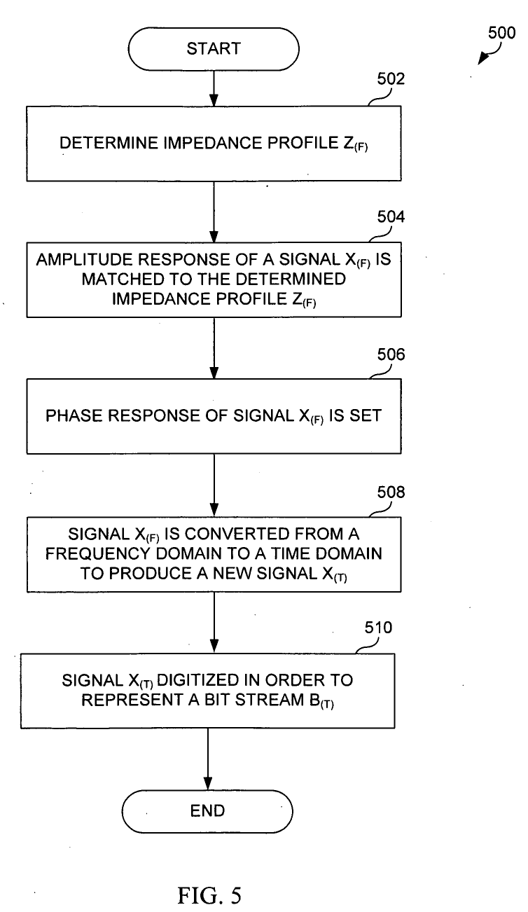

FIG. 5 provides a logic flow diagram of a methodology of generating a pseudo random bit pattern with desired harmonic properties in accordance with embodiments of the present invention. Operations 500 begin in Step 502 where an impedance profile of an IO interface may be determined. This IO interface may be associated with an electronic circuit or digital system such as the integrated circuit provided in FIG. 1. In Step 504 the amplitude response of a Signal X_{(f)} is matched to the determined impedance profile of the IO interface provided by Step 502. In Step 506 a phase response of Signal X_{(f)} is set. In Step 508 Signal X_{(f)} is converted from a frequency domain to a time domain to produce a new Signal x₍ₜ₎. In Step 510 this signal may be digitized in order to represent a bit stream B₍ₜ₎. This bit stream may be then used as a switching pattern for the IO interface to determine an SSN. The phase response of the signal X_{(f)} provided in Step 506 may be a random response. The random response may be Phase(X_{(f)})=Π*v where v is a uniformly distributed random variable between −1 and 1.

Digitizing of Signal x₍ₜ₎ may be performed using a threshold algorithm. This threshold algorithm may employ a suitably defined threshold. The impedance profile of the IO interface of the digital system may be based on a model of an electronic circuit such as that provided by a mathematical model or a SPICE model which may be simulated on a computer system. The model of the circuit may include a variety of components present in the circuit, including (but not limited to) resistors, capacitors, inductors, power supplies, integrated circuits, and a voltage regulator module. The power and ground planes may be modeled as a mesh of transmission lines. The model may also include a plurality of drivers configured to switch between two different logic voltage levels. The system and method for SSN analysis may be configured to simulate the simultaneous switching of a large number of these drivers from one logic voltage to the other. In some embodiments, transmission lines may be terminated with an open circuit, while in others, transmission lines may be terminated using resistors.

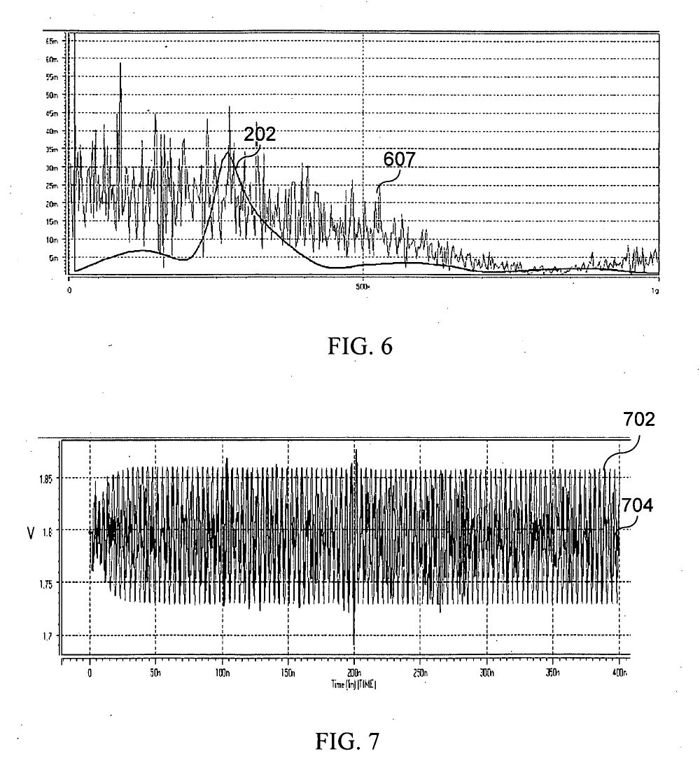

FIG. 6 provides a switching current I_{(f)} profile associated with the pseudo random bit pattern 607 generated as described with reference to FIG. 5. As can be seen in FIG. 6 much less energy of the bit pattern is wasted as the amplitude has been made to match the impedance profile 202.

FIG. 7 provides a direct comparison of these improved results. FIG. 7 shows the SSN generated for repetitive and randomized bit patterns. Trace 704 shows the SSN associated with randomized bit pattern generated in accordance with embodiments of the present invention while Trace 702 shows the SSN associated with repetitive bit patterns. As seen here Trace 704 clearly has a higher peak to peak SSN than Trace 702.

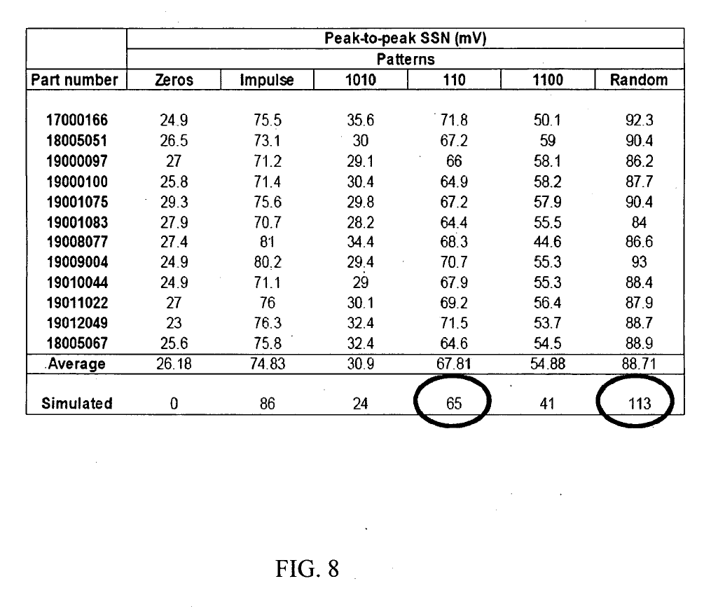

FIG. 8 provides a table of SSN measurements associated with various bit patterns. Table of FIG. 8 shows the measured peak to peak SSNs for various repetitive bit patterns and for a pseudo random bit pattern generated as described with reference to FIG. 5. As seen from the results the random pseudo random bit pattern clearly provides a worsened case SSN.

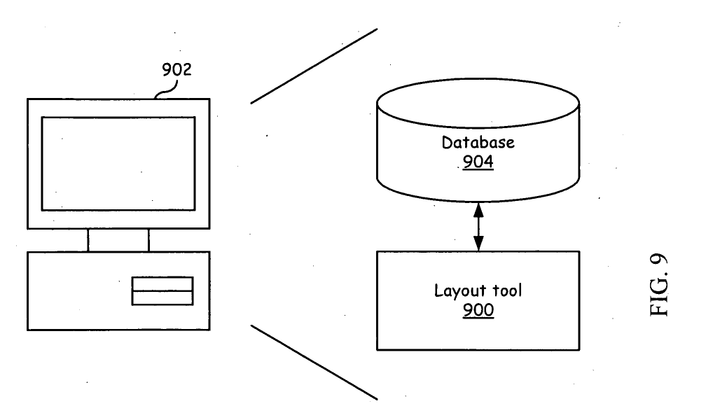

FIG. 9 provides a system operable to implement a methodology to determine a bit pattern that approximates a worst case SSN for memory or IO interfaces of digital systems in accordance with embodiments of the present invention. A model of the digital system may be contained in Databases 904. A Computer System 902 may be configured to determine an impedance profile of a digital system contained within or modeled with database 904. This impedance profile would then be amplitude matched to produce a signal X_{(f)}. The phase response of the signal X_{(f)} is set. Then the signal X_{(f)} is converted from the frequency domain to a time domain. The time domain signal may then be digitized to represent a bit stream. Then the bit stream may be provided to simulate simultaneous switching of the IO interface to determine the affects of SSN on the proposed digital system. This allows IO systems to be laid out such that individual IO meets local SSO requirements.

Another embodiment may utilize a layout tool 900 to implement IC design and layout circuit in accordance with embodiments of the present invention. To affect the layout of IO interfaces, IC designers often use layout tools to ensure the compliance with and automate the layout of the various IC layers in accordance with the design rules associates with fabrication of a particular IC. Layout tool 900 that may be implemented with a computer or processing system. Processing systems can be any suitable computer-processing device that includes memory for storing and executing logic instructions, and is capable of interfacing with other processing systems. In some embodiments, processing systems can also communicate with other external components via an attached network. Various input/output devices, such as keyboard and mouse (not shown), can be included to allow a user to interact with components internal and external to processing systems. Additionally, processing systems can be embodied in any suitable computing device, and so include personal data assistants (PDAs), telephones with display areas, network appliances, desktops, laptops, X-window terminals, or other such computing devices. Logic instructions executed by processing systems can be stored on a computer readable medium, or accessed by/transmitted to processing systems in the form of electronic signals. Processing systems can be configured to interface with each other, and to connect to external a network via suitable communication links such as any one or combination of T1, ISDN, or cable line, a wireless connection through a cellular or satellite network, or a local data transport system such as Ethernet or token ring over a local area network. The logic modules, processing systems, and circuitry described herein may be implemented using any suitable combination of hardware, software, and/or firmware, such as Field Programmable Gate Arrays (FPGAs), Application Specific Integrated Circuit (ASICs), or other suitable devices. The logic modules can be independently implemented or included in one of the other system components. Similarly, other components have been discussed as separate and discrete components. These components may, however, be combined to form larger, smaller, or different software modules, integrated circuits, or electrical assemblies, if desired.

Layout tools are software suites or packages that may include layout, verification, places out, schematic capture, and industry standard database conversion and support tools. Layout tools 900 facilitate the intricate layout design of ICs through the use of attached data bases. Layout tools in accordance with an embodiment of the present invention further facilitate IC design by allowing the die size to be reduced while considering the effects of SSN.

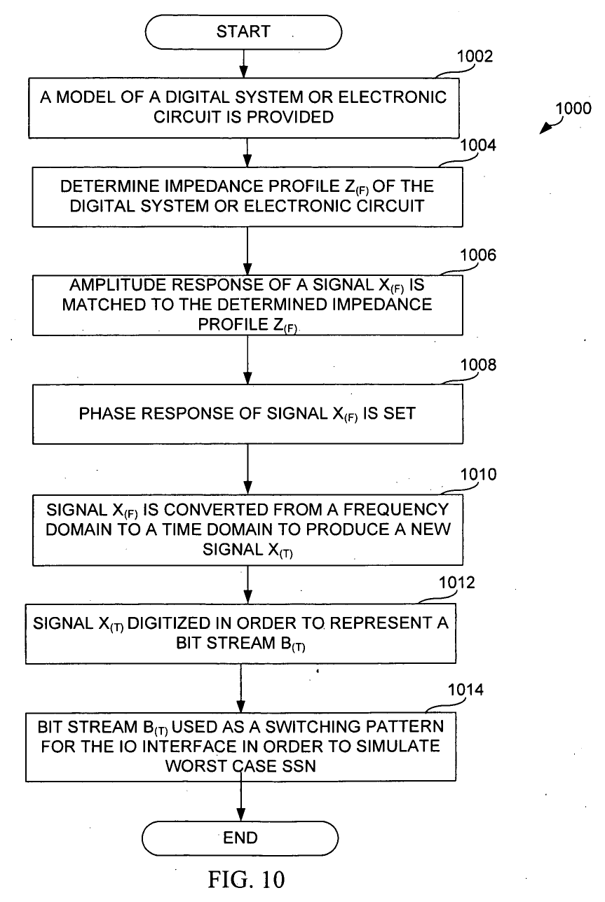

FIG. 10 provides a logic flow diagram of a method for analyzing SSN in a digital system or electronic circuit in accordance with embodiments of the present invention. Operations 1000 begin with Step 1002 where a model of a digital system or electronic circuit is provided to a computer system. The computer system then executes code in Step 1004 to determine and impedance profile of an IO interface of the digital system. In Step 1006 the amplitude response of the signal X_{(f)} may be matched to the impedance profile of the IO interface. In Step 1008 the phase response of the signal may be set. Step 1010 converts the signal from a frequency domain signal to a time domain signal. Then in Step 1012 the time domain signal will be digitized to represent a bit stream. This bit stream may be used in Step 1012 as a switching pattern for the IO interface in order to simulate worst case SSN and determine expected SSN noise. This allows a designer to address SSN during the design process such that local SSO requirements are met in the actual hardware.

In summary, embodiments of the present invention provide a methodology to determine a bit pattern that may excite a worst case or near worse case simultaneous switching noise (SSN) on a memory or input/output (IO) interface of a digital system. This methodology involves determining an impedance profile of the IO interface of the digital system. The amplitude response of signal X_{(f)} may be matched in the impedance profile of the IO interface. The phase response of the signal X_{(f)} is also set. The signal X_{(f)} having a matched amplitude response may be converted from a frequency domain signal to a time domain signal to produce a signal X₍ₜ₎. Signal X₍ₜ₎ the time domain signal X₍ₜ₎ may be digitized to represent a bit stream B₍ₜ₎. This bit stream may be used as a switching pattern to determine simultaneous switching noise of the IO interface of the digital system.

As one of average skill in the art will appreciate, the term “substantially” or “approximately”, as may be used herein, provides an industry-accepted tolerance to its corresponding term. Such an industry-accepted tolerance ranges from less than one percent to twenty percent and corresponds to, but is not limited to, component values, integrated circuit process variations, temperature variations, rise and fall times, and/or thermal noise. As one of average skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of average skill in the art will also appreciate, inferred coupling (i.e., where one element is coupled to another element by inference) includes direct and indirect coupling between two elements in the same manner as “operably coupled”. As one of average skill in the art will further appreciate, the term “compares favorably”, as may be used herein, indicates that a comparison between two or more elements, items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method comprising:
determining an impedance profile of an Input/Output (IO) interface of a digital system;
matching an amplitude response of a signal X_{(f)} to the impedance profile of the IO interface;
setting a phase response of the signal X_{(f)};
converting the signal X_{(f)} from a frequency domain to a time domain to produce signal x₍ₜ₎;
digitizing the signal x₍ₜ₎ to represent a bit stream b₍ₜ₎; and
using bit stream b₍ₜ₎ as a switching pattern for the IO interface to determine simultaneous switching noise (SSN).

2. The method of claim 1, wherein the phase response of the signal X_{(f)} comprises a random response.

3. The method of claim 2, wherein the phase response of the signal X_{(f)} comprises Phase(X_{(f)})=Π*v where v is a uniformly distributed random variable between −1 and 1.

4. The method of claim 1, wherein digitizing the signal x₍ₜ₎ to represent a bit stream b₍ₜ₎ is performed using a thresholding algorithm.

5. The method of claim 1, wherein the impedance profile of the IO interface of the digital system is based on a model of an electronic circuit.

6. The method of claim 1, comprising
simulating simultaneous switching of a two or more of said drivers from a first voltage level to a second voltage level with bit stream b₍ₜ₎ as a switching pattern for the IO interface to determine SSN.

7. The method of claim 1 wherein the impedance profile of the IO interface of the digital system is based on a mathematical model of the digital system comprising an electronic circuit.

8. The method of claim 1 wherein the impedance profile of the IO interface of the digital system is based on a SPICE model of the digital system.

9. A system comprising:
a model of a digital system; and
a computer system configured to:
determine an impedance profile of an Input/Output (IO) interface of the digital system;
match an amplitude response of a signal X_{(f)} to the impedance profile of the IO interface;
set a phase response of the signal X_{(f)};
convert the signal X_{(f)} from a frequency domain to a time domain to produce signal x₍ₜ₎;
digitize the signal x₍ₜ₎ to represent a bit stream b₍ₜ₎; and
simulate simultaneous switching of the IO interface using bit stream b₍ₜ₎ as a switching pattern for the IO interface to determine simultaneous switching noise (SSN).

10. The system of claim 9, wherein the phase response of the signal X_{(f)} comprises a random response.

11. The method of claim 10, wherein the phase response of the signal X_{(f)} comprises Phase(X_{(f)})=Π*v where v is a uniformly distributed random variable between −1 and 1.

12. The system of claim 9, wherein digitizing the signal x₍ₜ₎ to represent a bit stream b₍ₜ₎ is performed using a thresholding algorithm.

13. The system of claim 9, wherein the impedance profile of the IO interface of the digital system is based on the model of the digital system.

14. The system of claim 9 wherein the impedance profile of the IO interface of the digital system is based on a mathematical model of the digital system.

15. The system of claim 9 wherein the impedance profile of the IO interface of the digital system is based on a SPICE model of the digital system.

16. A method for analyzing simultaneous switching noise (SSN) in a digital system, the method comprising:
providing a model of the digital system;
determining an impedance profile of an Input/Output (IO) interface of the digital system based on the model;
matching an amplitude response of a signal X_{(f)} to the impedance profile of the IO interface;
setting a phase response of the signal X_{(f)};
converting the signal X_{(f)} from a frequency domain to a time domain to produce signal x₍ₜ₎;
digitizing the signal x₍ₜ₎ to represent a bit stream b₍ₜ₎; and
using bit stream b₍ₜ₎ as a switching pattern for the IO interface to determine simultaneous switching noise (SSN).

17. The method of claim 16, wherein the phase response of the signal X_{(f)} comprises a random response.

18. The method of claim 17, wherein the phase response of the signal X_{(f)} comprises Phase(X_{(f)})=Π*v where v is a uniformly distributed random variable between −1 and 1.

19. The method of claim 16, wherein digitizing the signal x₍ₜ₎ to represent a bit stream b₍ₜ₎ is performed using a thresholding algorithm.

20. The method of claim 16, comprising
simulating simultaneous switching of the IO interface with bit stream b₍ₜ₎ as a switching pattern for the IO interface to determine SSN.

21. The method of claim 16 wherein the impedance profile of the IO interface of the digital system is based on a mathematical model of the digital system or a SPICE model of the digital system.
